(19) United States
(12) Patent Application Publication
(10) Pub. No.: US 2011/0108084 A1
(43) Pub. Date: May 12, 2011

(54) In-line flexible diode assembly for use in photovoltaic modules and method of making the same

(76) Inventors: Anthony C. Tisler, Troy, MI (US); Paul E. Sims, Teledo, OH (US); Phillip N. Hildebrandt, Perrysburg, OH (US); Kenneth C. Draeger, Teledo, OH (US); Aarohi Vijh, Sylvania, OH (US)

(21) Appl. No.: 12/925,557

(22) Filed: Oct. 25, 2010

Related U.S. Application Data
(60) Provisional application No. 61/254,725, filed on Oct. 25, 2009.

(51) Int. Cl. H01L 31/05; H01L 31/042; H01L 31/18; B32B 38/00

(52) U.S. Cl. 136/244; 156/222

(57) ABSTRACT

A photovoltaic module is provided. The photovoltaic module comprises a first solar cell in an electrical series connection with a second solar cell. The first and second solar cells each have an first edge portion, a center portion, and a second edge portion. The photovoltaic module also comprises a flexible diode assembly having an anode side, a first diode, and a cathode side. The flexible diode assembly is in an electrical parallel connection with the first solar cell and positioned so that the cathode side, the diode, and a portion of the anode side are within an edge portion of the first solar cell. The portion of the anode side that is outside of the edge portion of the first solar cell is disposed for electrical connection with the second solar cell.

A method of making a flexible photovoltaic module using a flexible diode assembly is also provided.

### RELATED APPLICATION

This application is claiming the benefit, under 35 U.S.C. 119(e), of the provisional application which was filed on Oct. 25, 2009 under 35 U.S.C. 111(b), which was granted Ser. No. 61/254,725. This provisional application is hereby incorporated by reference.

### BACKGROUND OF THE INVENTION

Photovoltaic (PV) modules may be constructed by electrically connecting one or more solar cells in series and encapsulating the cells. Solar cells are connected in series to provide a useful module voltage that can, for instance, charge a battery. Series connection also requires that the solar cells be “current matched” so that excess current from one solar cell does not cause deleterious heating effects in other solar cells driven by the excess current. However, when connected in series, if an individual cell in the PV module becomes shaded by cloud cover, debris, or for another reason a large amount of heat may be generated as the shaded cell is driven by the rest of the solar cell string.

To overcome this problem, bypass diode assemblies can be integrated into a PV module 10. A bypass diode assembly allows the current generated by the non-shaded cells to bypass the shaded cell without incurring the above-mentioned problems. As shown in FIG. 1, the prior art diode assembly 12 comprises a diode 13 attached to an anode side 14 and a cathode side 16. The anode side 14 and the cathode side 16 each have an L-shaped terminal connector 18. Each terminal connector 18 may make a terminal connections 20, 22 with busbars 24 located on each solar cell 26 or an interconnect 28.

When utilized in a flexible PV module, the L-shaped terminal connectors 18 help to minimize the thickness of the module by allowing the diode 13 to be out of alignment with the solar cell busbars 24 to which they are connected. Also, by positioning the diode 13 in this manner, the stress on the connection points 30 between the diode 13 and the anode side 14 and the cathode side 16 is reduced when the PV module 10 is flexed. However, there are several drawbacks to utilizing the prior art diode assembly 10.

For instance, positioning the diode 13 in non-alignment with the solar cell busbars 24 increases the amount of encapsulation 31 required to form the PV module 10. Thus, the footprint of the PV module 10 is increased. Additionally, while the prior art design reduces the stress on the connection points 30 between the diode 13 and the anode and cathode sides 14, 16 it does not eliminate it. Thus, when the PV module 10 is flexed, the connection points 30 are prone to failure. This is problematic in that the result is PV module failure and/or decreased power output. Finally, when utilizing large area solar cells, these prior art deficiencies may be compounded because two or more diode assemblies may be required for every solar cell.

The present invention relates to a flexible diode assembly which solves the above-described problems. More particularly, the invention relates to PV modules and methods of use that employ a flexible diode assembly not having the above-described problems with no or only a slight increase in module thickness.

### SUMMARY OF THE INVENTION

The present invention includes a photovoltaic module comprising a first solar cell in an electrical series connection with a second solar cell. The first and second solar cells each have a first edge portion, a center portion, and a second edge portion. The photovoltaic module also comprises a flexible diode assembly comprising an anode side, a first diode, and a cathode side. The flexible diode assembly is in an electrical connection with the first solar cell and positioned so that the cathode side, the diode, and a portion of the anode side are within an edge portion of the first solar cell. The portion of the anode side that is outside of the edge portion of the first solar cell is disposed for electrical connection with the second solar cell.

The present invention also provides a photovoltaic module comprising a first solar cell having a first surface and a second surface. The photovoltaic module also comprises a second solar cell located adjacent the first solar cell but not in contact with the first solar cell, the second solar cell having a first surface and a second surface. The photovoltaic module further comprises an interconnect comprising a metal foil. The interconnect is attached to the first solar cell and the second solar cell to form an electrical series connection between the first solar cell and the second solar cell. Additionally, the photovoltaic module comprises a flexible diode assembly attached to a surface of one of the first solar cell or the second solar cell and to the interconnect.

A method of making a flexible photovoltaic module using a flexible diode assembly is also provided. The method comprises attaching a cathode side of a flexible diode assembly to either a top or bottom surface of a first solar cell. The method also comprises attaching an anode side of said flexible diode assembly to a top surface of a second solar cell. Additionally, the method comprises bending the first solar cell and the second solar cell such that the flexible diode assembly flexes on the anode side, the cathode side, or both sides.

### BRIEF DESCRIPTION OF THE DRAWINGS

FIG. 1 is a top view of a bypass diode assembly connected to two solar cells;

FIG. 2 is a side perspective view of a bypass diode assembly of the present invention;

FIG. 3 is an exploded view of a bypass diode assembly of the present invention;

FIG. 4 is a bottom perspective view of a bypass diode assembly of the present invention;

FIG. 5 is a bottom perspective view of a bypass diode assembly of the present invention;

FIG. 6 is an exploded view of a bypass diode assembly of FIG. 5;

FIG. 7 is an electrical schematic of a PV module of the present invention;

FIG. 8 is a partial cross-sectional view of an embodiment of FIG. 7;

FIG. 9 is a partial cross-sectional view of an embodiment of FIG. 7;

FIG. 10 is partial top view of the FIG. 7;

FIG. 11 is an electrical schematic of a PV module of the present invention; and

FIG. 12 is partial cross-sectional view of FIG. 11.

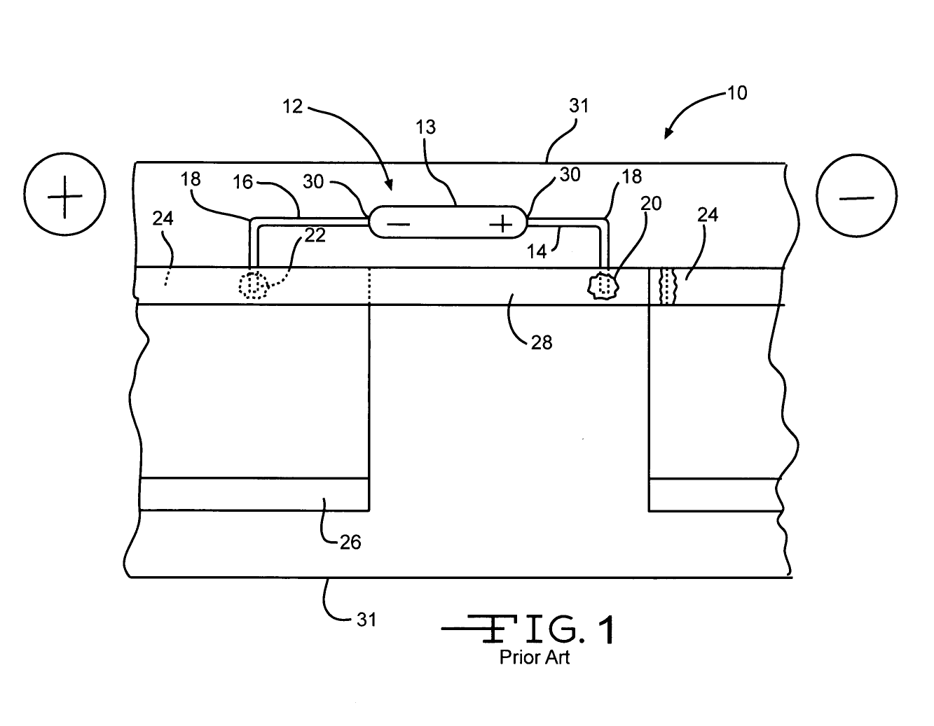

### DETAILED DESCRIPTION OF THE PREFERRED EMBODIMENT(S)

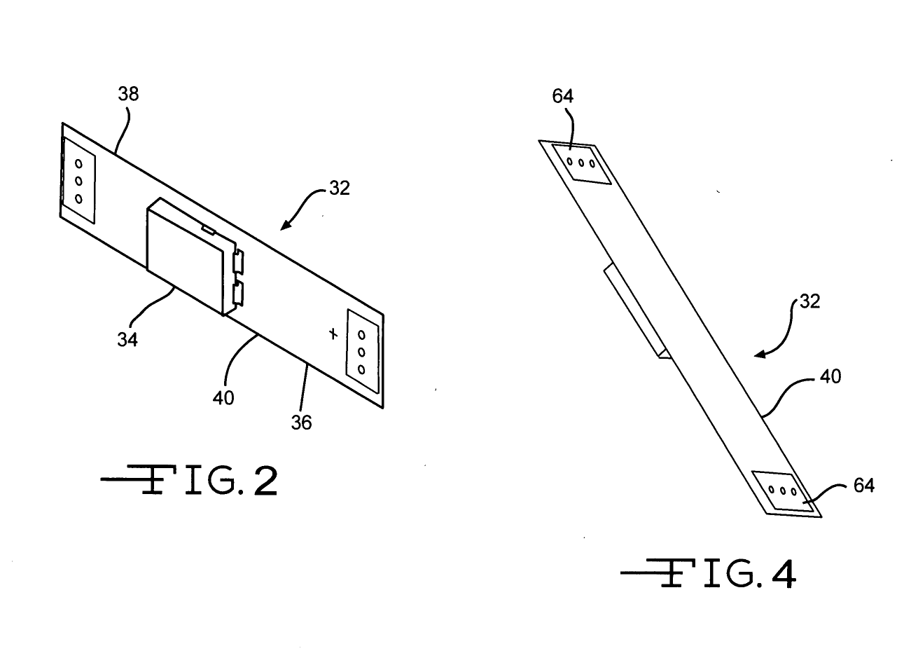

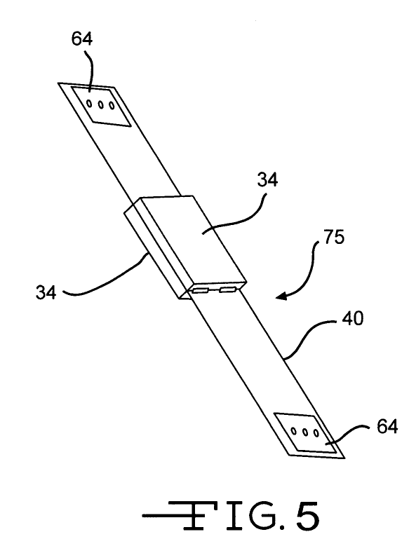

It is to be understood that the invention may assume various alternative orientations and step sequences, except where expressly stated to the contrary. It should also be appreciated that the specific devices and processes illustrated in FIGS. 2-12, and described in the following specification are simply exemplary embodiments of the inventive concepts defined in the appended claims. For example, although the present invention will be described in connection with PV modules having at least one amorphous silicon (a-Si) single junction (SJ) or a triple junction a-Si the present invention is not so limited. As such, the present invention may include PV cell material layers and PV cells having at least one single junction (SJ) of cadmium telluride (CdTe), amorphous silicon germanium (a-SiGe), amorphous silicon (a-Si), crystalline silicon (c-Si), microcrystalline silicon (mc-Si), nanocrystalline silicon (nc-Si), CIS, CIGS, or CIGSe.

Referring to FIGS. 2-4, a flexible diode assembly 32 for use in a PV module 72, 74 is illustrated. The flexible diode assembly 32 comprises a diode (or first diode) 34, an anode side 36, and a cathode side 38. The anode side 36 and the cathode side 38 forms a circuit board 40. Also, it is preferred for the present invention that the flexible diode assembly anode side 36, diode 34, and cathode side 38 are axially aligned. The flexible diode assembly 32 also comprises an insulating flexible substrate 42. The insulating substrate 42 has a first surface 44 and a second surface 46. The insulating substrate 42 comprises a polymer such as a polyimide. A preferred polyimide is known as Kapton, although other polyamides are capable of being used as the insulating substrate 42 in the present invention. The insulating substrate 42 also includes a plurality of vias 48 extending from the first surface 44 through the insulating substrate 42 to the second surface 46. The vias 48 may serve several functions. For instance, the vias may allow heat to be dissipated from the flexible diode assembly 32 or may allow for electrical communication through the insulating substrate 42.

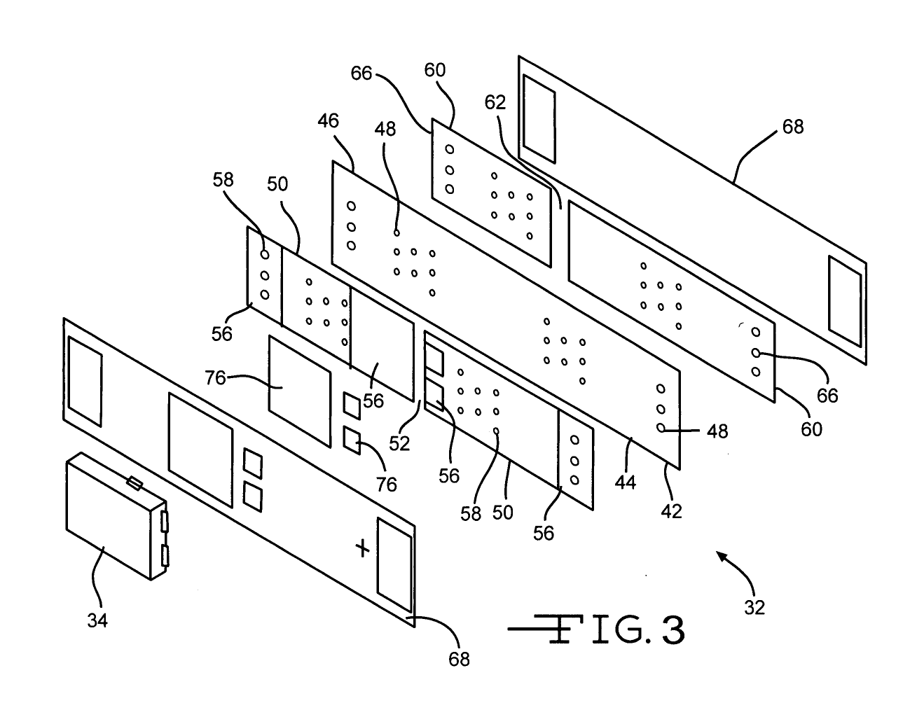

As shown in FIG. 3, the flexible diode assembly 32 also comprises a first pair of conductive metal foils 50 disposed on the insulating substrate first surface 44. Generally, the metal foils 50 do not contact each other, i.e. a space 52 or a gap exists between them. A preferred material for the first pair of metal foils 50 is copper or alloys thereof. However, other metals may be utilized as a foil material. The first pair of metal foils 50 can have surface portions covered by a plating metal 56. The plating metal 56 may comprise a metal which is more corrosion or oxidation resistant than the first metal foil material. For instance, the plating metal 56 may be gold or tin or alloys thereof. However, those skilled in the art would appreciate that another metal may be utilized as the plating metal 56. The first pair of metal foils 50 also comprises vias 58. The vias 58 extend through the first pair of metal foils 50. Generally, the first pair of metal foil vias 58 are aligned with and are equal in number to the substrate vias 48.

The flexible diode assembly 32 also comprises a second pair of conductive metal foils 60 disposed on the insulating substrate second surface 46. The second pair of metal foils 60 are spatially aligned in a parallel relationship and in electrical communication with the first pair of metal foils 50. Generally, the second pair of metal foils 60 do not contact each other, i.e. a space 62 or a gap exists between them to prevent shorts from occurring. A preferred second pair of metal foil material is copper or alloys thereof. However, other metals may be utilized as foil material. The second pair of metal foils 60 may have surface portions covered by a plating metal 64. The plating metal 64 may comprise gold, tin, or alloys thereof. The second pair of metal foils 60 also comprises vias 66. The vias 66 extend through the second pair of metal foils 60. Generally, because of their function, the second pair of metal foil vias 66 are aligned with and in equal number to the substrate vias 48.

The metal foil vias 58, 66 are plated through the insulating substrate 42 which gives electrical and thermal connection between the metal foils 50, 60. Additionally, it should be appreciated that the metal foils 50, 60 of the present invention may be patterned in a variety of configurations to provide the correct circuit topology for components mounted on the circuit board 40.

The flexible diode assembly 32 may also include a solder mask 68. Portions of the metal foils 50, 60 can be covered or encapsulated with the solder mask 68. Preferably, the portions of the metal foils 50, 60 which are not covered with or encapsulated in the solder mask 68 are covered by the plating material 56, 64. The solder mask 68 may be a polymer. A preferred solder mask material is a polyimide such as Kapton. However, other polymers and specifically other polyimides may be utilized as the solder mask 68.

The diode 34 is connected to the first pair of metal foils 50. The PV module 72, 74 may include interconnected large area triple junction a-Si solar cells. Large area triple junction a-Si solar cells may produce a current above 10 amps. Hence, the diode 34 may be rated to conduct current above 10 amps, preferably 12 amps. However, the diode 34 is not limited to ratings above 10 amps. Thus, the diode may also be rated to conduct current for much lower amperage. For instance, the diode 34 of the present invention may be rated for a current of 1 amp or less or magnitudes between 1 and 12 amps. A preferred type of diode 34 for use in the present invention is a Silicon Schottky diode. A Silicon Schottky diode is preferred not only for its high current capabilities but also for its low voltage drop. However, other types of diodes may be utilized in practicing the present invention. For instance, a PN or a specifically a germanium PN diode may also be utilized instead of a Silicon Schottky diode.

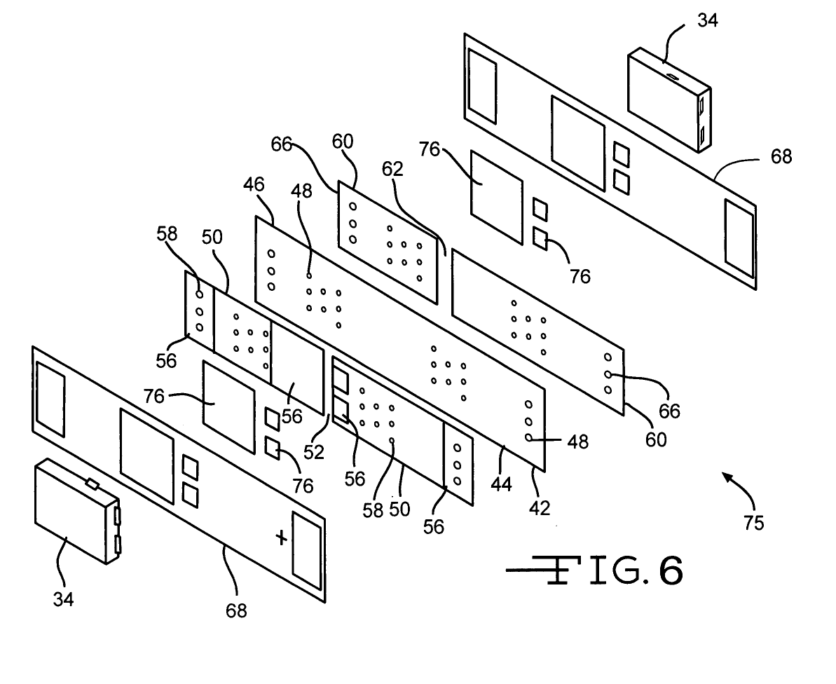

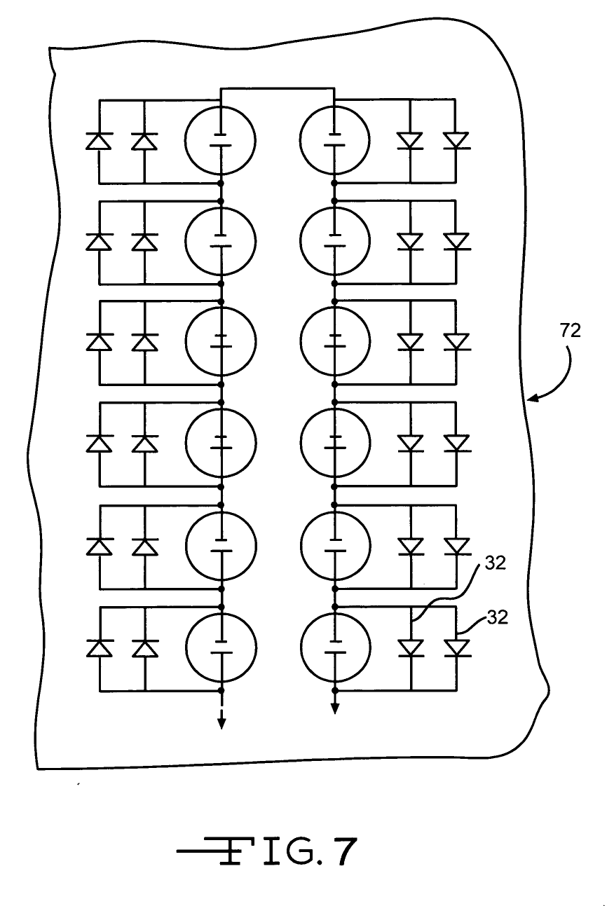

FIGS. 5 and 6 depict another flexible diode assembly 75 for use in the PV module 72, 74 of the present invention. The flexible diode assembly 75 has an anode side 36, a cathode side 38, an insulating flexible substrate 42, metal foil pairs 50, 60, and vias 48, 58, 66 which are similar to those described, above. As shown in FIGS. 5 and 6, the flexible diode assembly 75 includes a first diode 34 and a second diode 34. The second diode 34 may be of similar type and/or rating as the first diode 34 as described, above. The second diode 34 is attached to a second pair of conductive metal foils 60. The second pair of metal foils 60 can have surface portions covered by a plating metal, as described for the first pair of metal foils 50, above. The plating metal may be of similar in type and composition as the plating metal 56 as described, above. As depicted, in this embodiment, the first and second diodes 34, 34 are aligned but located on opposite surfaces of the circuit board 40.

For some applications of the present invention, a first and a second diode 34, 34 is advantageous in a flexible diode assembly because it provides a higher current carrying capacity. The flexible diode assembly 75 is also advantageous in that it allows the diodes 34, 34 to be in intimate thermal contact with each other.

As shown in FIG. 3, the flexible diode assembly 32 may utilize solder 76 for attaching the first diode 34 to the first pair of metal foils 50. As shown in FIG. 6, the flexible diode assembly 75 may also utilize solder 76 for attaching the first diode 34 to the first pair of metal foils 50 and for attaching the second diode 34 to the second pair of metal foils 60. The solder material attaches portions of the diode 34 or diodes 34, 34 to the anode side 36 and the cathode side 38 of the flexible diode assembly 32, 75. A preferred solder material is SAC (96.5Sn/3.0Ag/0.5Cu) solder or another solder with an appropriate melting point.

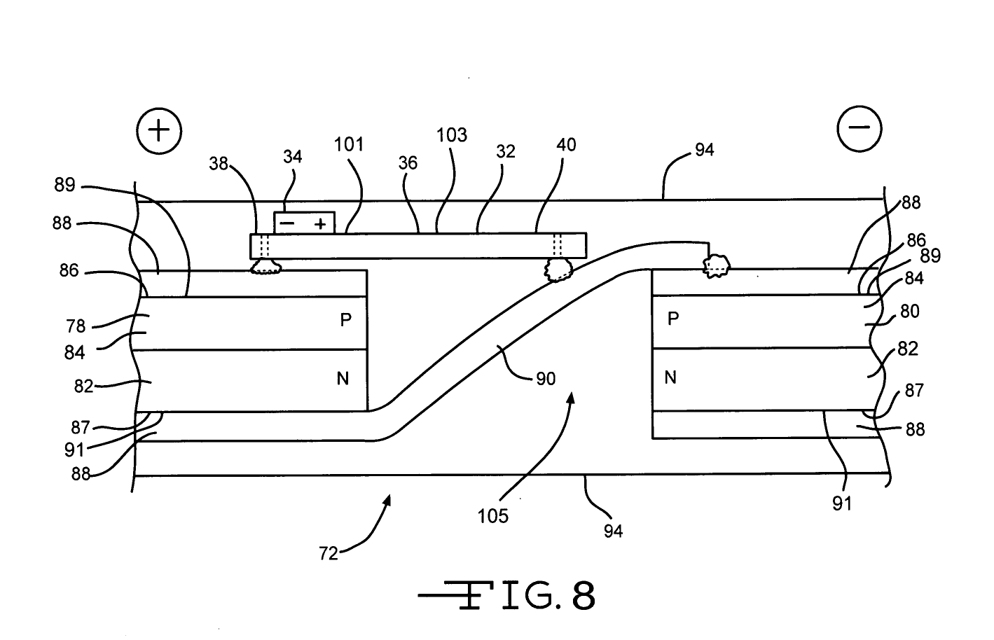

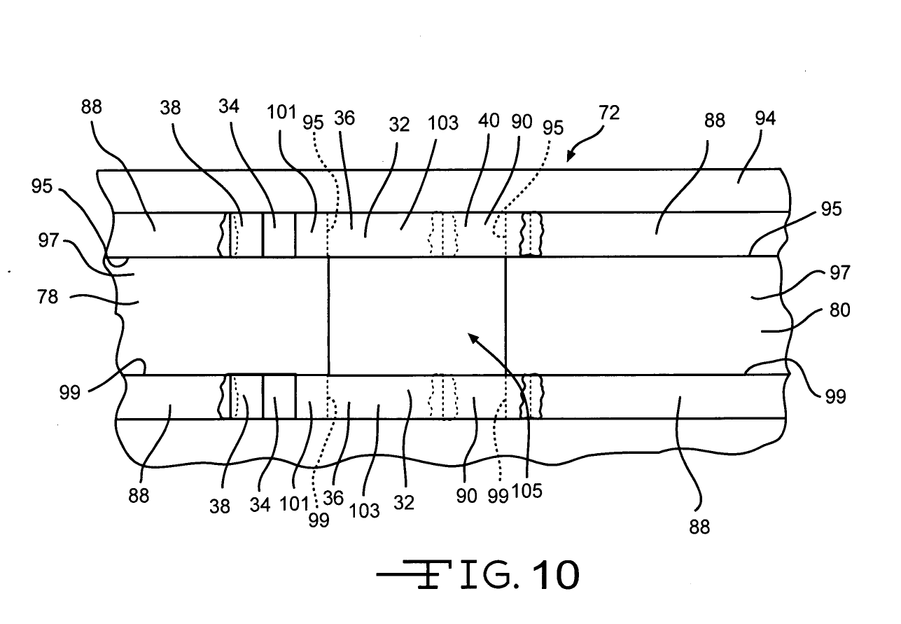

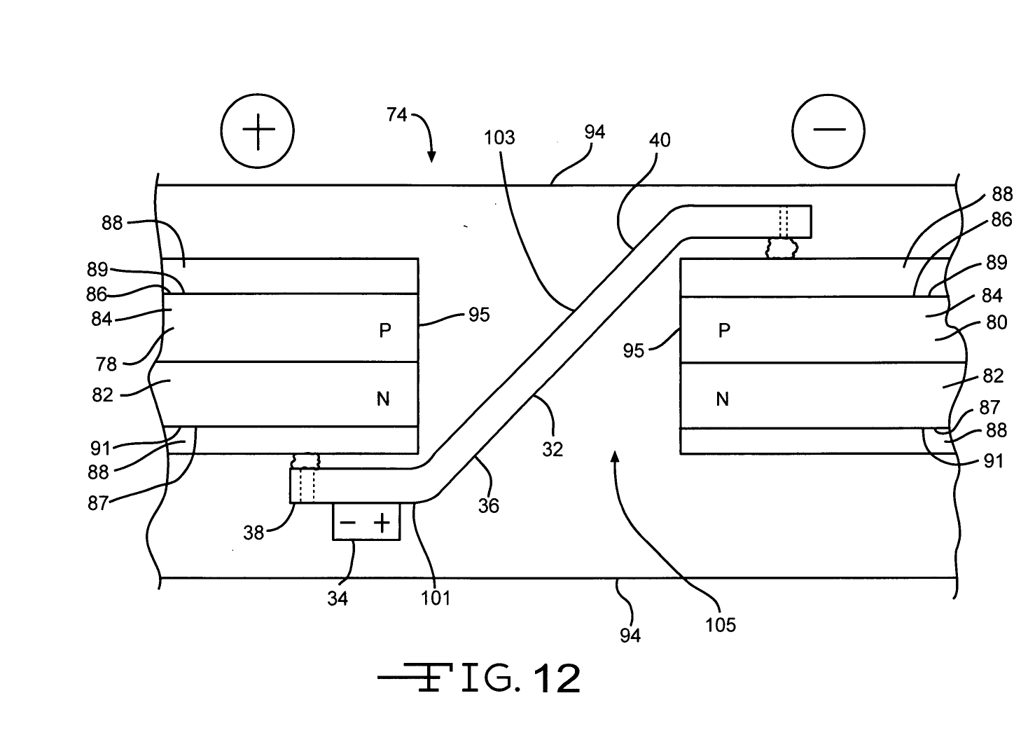

The present invention will now be described with regard to flexible diode assembly 32. However, it should be understood that the flexible diode assembly 75 of FIG. 9 could be substituted for or used in combination with the flexible diode assembly 32 unless stated to the contrary. As shown in FIGS. 7-12, the present invention is a PV module 72, 74 comprising at least one flexible diode assembly 32. Referring now to FIGS. 7-10, the flexible diode assembly 32 is utilized as a bypass diode assembly to perform a current bypass function. Whereas, in FIGS. 11-12, the flexible diode assembly 32 is utilized as a blocking diode assembly to perform a current blocking function. It should be appreciated that flexible diode assembly 75 may also be utilized as a blocking diode assembly in the PV module 74 or to provide a current blocking function in the PV module 74.

Preferably, the PV module 72, 74 is a flexible PV module. For the present invention, flexible PV module may mean that a PV module solar cell can be placed in non-coplanar alignment or bent with respect to another solar cell encapsulated within the module. Flexible PV module could also mean that the PV module can be rolled-up for transportation or storage. An example of a flexible PV module suitable for practicing the present invention is the XR-12 and/or the XR-36 sold by the Xunlight Corporation.

As best seen in FIGS. 7-9 and 11-12, the PV module 72, 74 comprises a first solar cell 78 and a second solar cell 80 in an electrical series connection. FIG. 7 shows the PV module 72 may comprises twelve solar cells in electrical series connection. FIG. 11 shows the PV module 74 may comprise eight solar cells in electrical series connection. It should be understood that the PV module 72, 74 of the present invention is not limited to a specific number of solar cells and it may comprise many times more or many times less than twelve or eight solar cells, respectively.

As stated, the PV module 72, 74 comprises first and second solar cells 78, 80 in an electrical series connection. Those skilled in the art would appreciate that for a-Si solar cells, the solar cells may be in an n-i-p orientation. Those skilled in the art would appreciate that, in another embodiment, the PV module 72, 74 may comprise a-Si solar cells in a p-i-n orientation. As such, the series connection may be made by connecting an N portion 82 of the first solar cell 78 with a P portion 84 of the second solar cell 80 or vice versa. Each solar cell 78, 80 has a first surface 86 and a second surface 87.

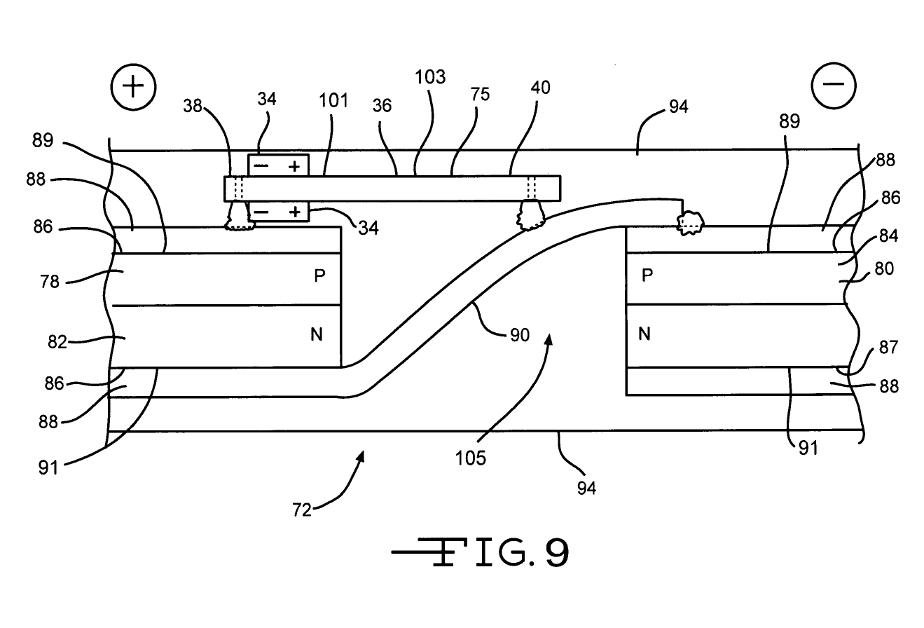

In the embodiment depicted in FIGS. 8 and 9, when the flexible diode assembly 32, 75 is performing a bypass function, the electrical series connection between the first solar cell 78 and the second solar cell 80 is made with a top surface to bottom surface interconnect 90. The interconnect 90 is preferably a metal foil. In another embodiment, the top surface to bottom surface interconnection could also be made between a top surface 89 of the first solar cell 78 and a bottom surface 91 of second solar cell 80. In an embodiment, each solar cell first surface 86 is the top surface 89 and each solar cell second surface 87 is the bottom surface 91. As known to those skilled in the art, the top surface may be the active surface, i.e. the surface upon which sunlight enters the PV module 72 and is absorbed by the solar cells 78, 80.

The solar cell N and P portions 82, 84 and first and second surfaces 86, 87 may have electrodes or copper busbars 88 attached to them. Thus, the series interconnection may be made by connecting the electrodes or busbars 88 attached to the surfaces 86, 87 of the solar cells 78, 80. Those skilled in the art would appreciate that there are multiple ways within the art to attach the electrodes or the busbars 88 to the solar cell surfaces 86, 87.

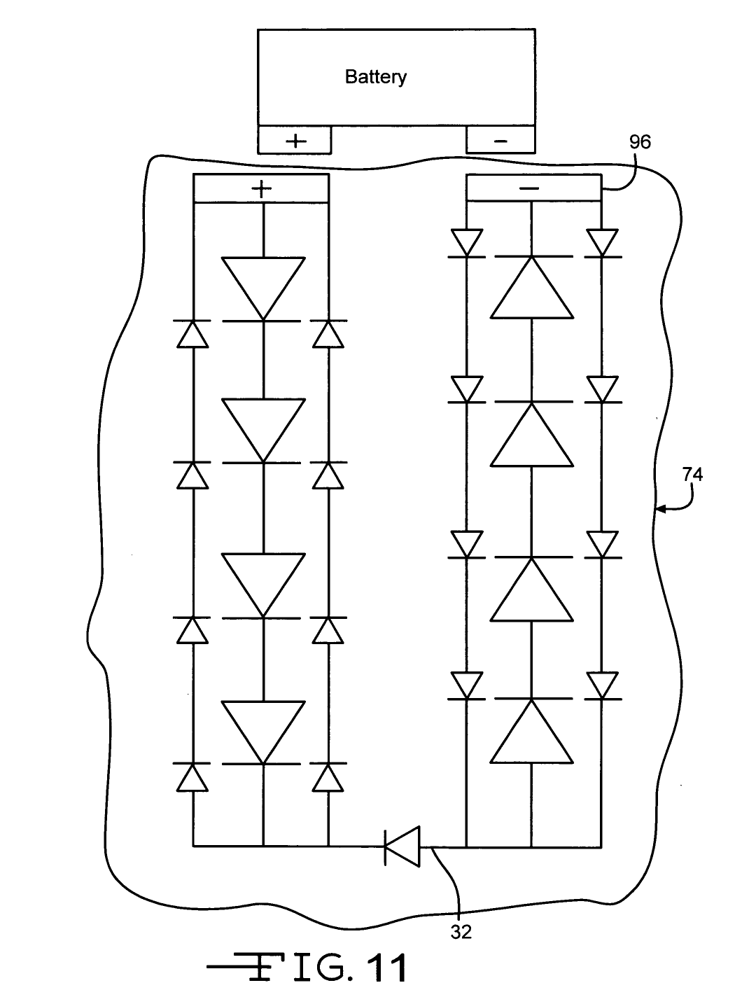

As shown in the embodiments of FIGS. 7-9, when the flexible diode assembly 32, 75 is performing a bypass function, the flexible diode assembly 32 is in an electrical parallel connection with the first solar cell 78. As shown in FIGS. 7 and 10, a pair of the flexible diode assemblies 32 may be utilized with either of the solar cells 78, 80 to perform a bypass function. As shown in FIG. 7, the PV module 72 may comprise a plurality of flexible diode assemblies 32.

As shown in FIG. 8, the flexible diode assembly 32 comprises the anode side 36, the diode 34, and the cathode side 38. As shown in FIG. 9, the flexible diode assembly 75 comprises the anode side 36, first and second diodes 34, 34, and the cathode side 38. The flexible diode assembly cathode side 38 may be attached to the P portion 84 of the first solar cell 78 or the busbar 88. Additionally, the anode side 36 may be attached to the interconnect 90. The interconnect 90 may be attached to the second surface 87 of the first solar cell 78 and the second solar cell first surface 86 to form an electrical series connection between the first solar cell 78 and the second solar cell 80. Those skilled in the art would appreciate that this orientation could be reversed so that the flexible diode assembly cathode side 38 is attached to the P portion 84 of the second solar cell 80 with the anode side 36 attached to an interconnect, with that interconnect attached to the second surface 87 of the second solar cell 80 and the first solar cell first surface 86 to form an electrical series connection between the first solar cell 78 and the second solar cell 80. Preferably, the flexible diode assembly 32 is connected to either the first and second solar cells 78, 80, the busbars 88, or the interconnect 90 via soldering.

Regardless, in an embodiment, the flexible diode assembly 32 is positioned within an edge portion of the solar cells 78, 80. As best shown in FIG. 10, the first solar cell 78 and second solar cell 80 each have a first edge portion 95, a second edge portion 99, and a center portion 97 located between the first and second edge portions 95, 99. The flexible diode assembly 32 is positioned so that the cathode side 38, the first diode 34, and a portion of the anode side 101 are within an edge portion 95 of the first solar cell 78. As depicted, when two flexible diode assemblies are provided, each flexible diode assembly 32 is positioned so that the cathode side 38, the first diode 34, and a portion of the anode side 101 are within an edge portion 95, 99 of the first solar cell 78. When flexible diode assembly 75 is substituted for flexible diode assembly 32, both diodes 34, 34 would be positioned within the edge portion 95 of the first solar cell 78.

A portion 103 of the anode side that is outside of the edge portion 95 of the first solar cell 78 is disposed for electrical connection with the second solar cell 80 via the interconnect 90. Additionally, as depicted, the flexible diode assembly 32 may be in alignment with the first edge portion 95 of the first solar cell 78 and with the first edge portion 95 of the second solar cell 80 and/or the solar cell busbars 88. When substituting the flexible diode assembly 75 for flexible diode assembly 32, the flexible diode assembly 75 is also in alignment with the first edge portion 95 of the first solar cell 78 and with the first edge portion 95 of the second solar cell 80 and/or the solar cell busbars 88. The busbars 88 are positioned within the edge portions 95, 99 of the solar cells 78, 80.

As described, above, the PV module 72 may comprise a plurality of flexible diode assemblies 32. As such, as best seen in FIG. 10, in an embodiment the PV module 72 may comprise a second flexible diode assembly 32 and a second interconnect 90 for providing a current bypass function of either the first solar cell 78 or the second solar cell 80. The second flexible diode assembly 32 is attached to the same surface of either the first solar cell 78 or the second solar cell 80 as the first flexible diode assembly 32 is attached to and is also attached to the second interconnect 90. The second flexible diode assembly 32 and the second interconnect 90 are in a spaced apart and parallel relationship with the first flexible diode assembly 32 and first interconnect 90. The second interconnect 90 is attached to the first solar cell 78 and the second solar cell 80 to form an electrical series connection between the first solar cell 78 and the second solar cell 80. The flexible diode assembly 75 may be substituted for the second flexible diode assembly 32.

As stated above, the flexible diode assembly 32 may perform a current blocking function. As depicted in FIG. 11, a flexible blocking diode assembly 32 may be utilized in charging a battery using a PV module 74. The PV module 74 charges the battery by illuminating at least portions of the PV module 74. The flexible blocking diode assembly 32 blocks battery discharge through the PV module 74 when PV module illumination is removed or obstructed.

As described, above, and shown in FIG. 12, the PV module 74 comprises a first solar cell 78 in an electrical series connection with a second solar cell 80. The first solar cell 78 and the second solar cell 80 are of the type described, above. The PV module 74 also comprises a flexible diode assembly 32 of the type described, above, in an electrical series connection with the first solar cell 78 and the second solar cell 80. Configured in this manner, the flexible diode assembly 32 forms the interconnection between the first solar cell 78 and the second solar cell 80. Preferably, the flexible blocking diode assembly 34 is connected to the first and second solar cells 78, 80 via soldering.

A shown in FIG. 12, the flexible blocking diode assembly 32 comprises the anode side 36, the first diode 34, and the cathode side 38. The flexible blocking diode assembly cathode side 38 is attached to the N portion 82 of the first solar cell 78 or the busbar 88. The anode side 36 may be attached to the P portion 82 of the first solar cell 78 or the busbar 88. Those skilled in the art would appreciate that the flexible blocking diode assembly 32 orientation could be reversed so that the flexible diode assembly cathode side 38 is attached to the N portion 82 of the second solar cell 80 with the anode side 36 attached to the a P portion 84 of the first solar cell 78.

The flexible blocking diode assembly 32 is positioned within an edge portion of the solar cells 78, 80, as described for the PV module 72, above. The flexible blocking diode assembly 32 is positioned so that the cathode side 38, the diode 34, and a portion of the anode side 101 are within an edge portion 95 of the first solar cell 78. It should be appreciated that flexible diode assembly 75 may be substituted for flexible diode assembly 32 to perform a blocking function. It should also be appreciated that the PV module 74 may comprise a flexible diode assembly 32 or a plurality of flexible diode assemblies performing a bypass function.

As shown in FIG. 12 a portion 103 of the anode side that is outside of the edge portion 95 of the first solar cell 78 is disposed for electrical connection with the second solar cell 80. Additionally, as described, above, for the flexible diode assemblies 32 performing a bypass function, the flexible blocking diode assembly 32 may be in alignment with the first edge portion 95 of the first solar cell 78 and with the first edge portion 95 of the second solar cell 80 and/or the solar cell busbars 88. One skilled in the art would appreciate that in these embodiments the flexible diode assembly 75 may also be substituted for the flexible blocking diode assembly 32 as described, above.

As best seen in FIG. 12, under normal conditions the first solar cell 78 is adjacent the second solar cell 80. However, the first solar cell 78 and the second solar cell 80 do not contact each other and therefore a space 105 is provided between the first solar cell 78 and the second solar cell 80. Preferably, the flexible blocking diode assembly 32 extends through the space 105 between the first solar cell 78 and the second solar cell 80.

The PV module 74 may also comprise a header 96 and/or a footer, as known to those skilled in the art. As described, above, the PV module 74 comprises the flexible blocking diode assembly 32 in an electrical series connection with a first solar cell 78 and a second solar cell 80. However, in another embodiment, the flexible blocking diode assembly 32 may be in an electrical series connection with only one solar cell. In this embodiment, the flexible blocking diode assembly 32 is in electrical communication with a solar cell and the header 96 or the footer.

The present invention is also directed to a method of making a flexible photovoltaic module 72, 74 using a flexible diode assembly 32.

The method comprises attaching a cathode side 38 of a flexible diode assembly 32 to either a top surface 86 or bottom surface 87 of a first solar cell 78. The method further comprises attaching an anode side 36 of said flexible diode assembly 32 to a top surface 86 of a second solar cell 80. In an embodiment, the anode side 36 of said flexible diode assembly 32 may be attached to a top surface 86 of a second solar cell 80 via an interconnect 90. Additionally, the method may comprise attaching a plurality of flexible diode assemblies 32 to the first and the second solar cells 78, 80 in the manner described, above.

Additionally, the method comprises bending the first solar cell 78 and the second solar cell 80 such that the flexible diode assembly 32, 75 flexes on the anode side 36, the cathode side 38, or both sides 36, 38.

The method may further comprise forming a flexible photovoltaic module 72, 74 by encapsulating the first solar cell 78, the second solar cell 80, and the flexible diode assembly 32. In forming the PV module 72, 74, the encapsulation material 94 may be a single material or may be multiple layers of different materials. A preferred encapsulation material is a polymer. More specifically, a preferred polymer is ethyl vinyl acetate (EVA). Other materials may be used as an encapsulant or as material layers between the solar cells and the encapsulant. For instance, Tedlar, fiberglass, Tefzel, and/or other insulating layers could all be utilized with EVA, singularly or in combination, in the PV modules 72, 74 of the present invention.

Regardless of whether the flexible diode assembly 32 is performing a blocking function or a bypass function and as best seen in FIGS. 8, 9, 12, under normal conditions the first solar cell 78 is coplanar, or substantially coplanar, with the second solar cell 80. This is also the case when the first solar cell 78 and the second solar cell 80 are encapsulated in the PV module 72, 74.

However, when physical forces are applied to the solar cells 78, 80 or the PV module 72, 74, the solar cells 78, 80 may bend with respect to one another. Thus, the solar cells 78, 80 may be placed in a non-coplanar relationship. For instance, a physical force could be applied to portions of the PV module 72, 74 to roll it up for transportation. A physical force may also be applied to portions of the PV module 72, 74 during preferred methods of manufacture. Thus, the method may further comprise forming a radial shape with the first solar cell 78, the second solar cell 80, and the flexible diode assembly 32.

The inventive method improves on the prior art methods of forming a PV module 72, 74 by providing portions of the flexible diode assembly 32 within an edge portion 95, 99 of the first solar cell 78. This allows the anode side 36, the cathode side 38, or both sides 36, 38 of the flexible diode assembly 32, 75 to flex without producing a mechanical force that separates the diode 34 from the flexible diode assembly circuit board 40. In an embodiment, either the anode side 36 or the cathode side 38 or both sides 36, 38 of the flexible diode assembly 32, 75 may deform but the first diode 34 will remain attached to the circuit board 40. In yet another embodiment, the method may further comprise applying a physical force in a direction opposite a first physical force to reduce or eliminate bending or to return the first and the second solar cells 78, 80 to a coplanar relationship.

The above detailed description of the present invention is given for explanatory purposes. Thus, it will be apparent to those skilled in the art that numerous changes and modifications can be made without departing from the scope of the invention. Accordingly, the whole of the foregoing description is to be construed in an illustrative and not a limitative sense. Therefore, specific dimensions, directions or other physical characteristics relating to the embodiments disclosed are not to be considered as limiting, unless the claims expressly state otherwise.

We claim:

1. A photovoltaic module, comprising:
a first solar cell in an electrical series connection with a second solar cell, the first and second solar cells each having a first edge portion, a center portion, and a second edge portion; and
a flexible diode assembly comprising an anode side, a first diode, and a cathode side, wherein the flexible diode assembly is in an electrical connection with the first solar cell and positioned so that the cathode side, the diode, and a portion of the anode side are within an edge portion of the first solar cell, wherein the portion of the anode side that is outside of the edge portion of the first solar cell is disposed for electrical connection with the second solar cell.

2. The photovoltaic module of claim 1, wherein the electrical series connection between the first solar cell and the second solar cell is made with a top surface to bottom surface interconnection.

3. The photovoltaic module of claim 1, wherein the flexible diode assembly comprises a second diode positioned on an opposite surface of the flexible diode assembly from the first diode.

4. The photovoltaic module of claim 1, wherein the flexible diode assembly can perform a bypass function.

5. The photovoltaic module of claim 1, wherein the flexible diode assembly can perform a blocking function.

6. The photovoltaic module of claim 1, wherein the photovoltaic module is a flexible photovoltaic module.

7. The photovoltaic module of claim 1, wherein the first solar cell edge portion is the first edge portion and wherein the flexible diode assembly is in alignment with the first solar cell first edge portion and the second solar cell first edge portion.

8. The photovoltaic module of claim 3, wherein the first diode and second diode are aligned with each other to place them in thermal contact and wherein both diodes are within the same edge portion of the first solar cell.

9. A photovoltaic module, comprising:
a first solar cell having a first surface and a second surface;
a second solar cell located adjacent the first solar cell but not in contact with the first solar cell, the second solar cell having a first surface and a second surface;
an interconnect comprising a metal foil, wherein the interconnect is attached to the first solar cell and the second solar cell to form an electrical series connection between the first solar cell and the second solar cell; and
a first flexible diode assembly attached to a surface of one of the first solar cell or the second solar cell and to the interconnect.

10. The photovoltaic module of claim 9, wherein the surface of the first solar cell or the second solar cell that flexible diode assembly is attached to is opposite a surface of that solar cell to which the interconnect is attached, a portion of the flexible diode assembly extending beyond the surface of the solar cell to which the flexible diode assembly is attached to engage the interconnect.

11. The photovoltaic module of claim 9, wherein the first surface of each solar cell is a top surface and wherein the second surface of each solar cell is a bottom surface.

12. The photovoltaic module of claim 9, further comprising a second flexible diode assembly and a second interconnect, wherein the second flexible diode assembly is attached to the same surface of either the first solar cell or the second solar cell as the first flexible diode assembly and to the second interconnect, wherein the second flexible diode assembly and second interconnect are in a spaced apart and parallel relationship with the first flexible diode assembly and first interconnect, and wherein the second interconnect is attached to the first solar cell and the second solar cell to form an electrical series connection between the first solar cell and the second solar cell.

13. The photovoltaic module of claim 9, wherein the photovoltaic module is a flexible photovoltaic module.

14. The photovoltaic module of claim 10, wherein the flexible diode assembly and the interconnect are attached between the first solar cell and the second solar cell.

15. The photovoltaic module of claim 11, wherein both solar cells are in an n-i-p orientation.

16. The photovoltaic module of claim 11, wherein both the flexible diode assemblies are oriented so that the diodes act as bypass diodes.

17. A method of making a flexible photovoltaic module using a flexible diode assembly, comprising:
attaching a cathode side of a flexible diode assembly to either a top or bottom surface of a first solar cell;
attaching an anode side of said flexible diode assembly to a top surface of a second solar cell; and
bending the first solar cell and the second solar cell such that the flexible diode assembly flexes on the anode side, the cathode side, or both sides.

18. The method of claim 17, wherein the flexible diode assembly provides a current bypass or a current blocking function.

19. The method of claim 17, further comprising forming a flexible photovoltaic module by encapsulating the first solar cell, the second solar cell, and the flexible diode assembly.

20. The method of claim 17, further comprising forming a radial shape with the first solar cell, the second solar cell, and the flexible diode assembly.
